(19) United States
(12) Patent Application Publication
(10) Pub. No.: US 2006/0208932 A1
(43) Pub. Date: Sep. 21, 2006

(54) Optical disk drive

(75) Inventor: Akira Mashimo, Tokorozawa-shi (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: TEAC Corporation

(21) Appl. No.: 11/376,426

(22) Filed: Mar. 15, 2006

(30) Foreign Application Priority Data
Mar. 16, 2005 (JP) 2005-075928

(51) Int. Cl. H03M 7/00

(52) U.S. Cl. 341/50

(57) ABSTRACT

An optical disk drive for readily setting a recording strategy for all optical disks. A table, where optimal recording strategies are set for respective pieces of identification information about optical disks, is stored in memory of a system controller. An average recording strategy is set for an optical disk which does not have any identification information. When data are recorded on the optical disk having no identification information, test data are recorded by means of an average recording strategy and another strategy determined by changing the average strategy, and a strategy—by means of which a rate of detection of a synchronizing signal assumes a predetermined value or more—is set as an optimal strategy. The rate of detection of the synchronizing signal of the mark and the rate of detection of the synchronizing signal of the space are computed, and the results of computation are compared with the predetermined value.

### PRIORITY INFORMATION

This application claims priority to Japanese Patent Application No. 2005-075928 filed on Mar. 16, 2005, which is incorporated herein by reference in its entirety.

### BACKGROUND OF THE INVENTION

1. Field of the Invention

The present invention relates to an optical disk drive, and more particularly, to setting of a recording strategy.

2. Description of Related Art

Conventionally, an optical disk drive capable of recording data, such as a DVD recorder, records data by setting a recording pulse into a desired pulse shape. Various manufacturers provide various types of optical disks in the market. Since recording characteristics of the optical disks are not uniform, a pulse value; i.e., laser power, is adjusted according to the type of an optical disk on which data are to be recorded.

Japanese Patent Laid-Open Publication No. 2003-6863 describes a technique for generating a signal reproduction clock signal on the basis of a synchronizing signal, and determining laser power in accordance with the duration of a time required to generate the clock signal.

In order to record data at high quality, data must be recorded by means of changing a pulse width, a pulse interval, and the like (a pulse value, a pulse width, and a pulse interval are generically called a “recording strategy”), in addition to the pulse value, according to the type of an optical disk.

Generally, data (identification information) pertaining to manufacture of an optical disk are recorded in a lead-in area of an optical disk. A relationship between identification information and a recording strategy is stored in advance in memory of the optical disk drive in the form of a table; identification information about an optical disk, on which data are to be recorded, is read; and reference is made to the table, so that a recording strategy conforming to the optical disk can be set.

However, the optical disks are sequentially, newly introduced into the market, and identification information which does not appear in the table can also exist. Moreover, there can be an optical disk whose identification information is not provided or is unreadable. In such a case, a recording strategy has to be set separately from a table. A standard recording strategy can also be recorded in a table on an optical disk where no identification information exists. However, there is no guarantee that the thus-set standard recording strategy is optimal for the optical disk, and recording quality of data cannot be insured.

As a matter of course, processing for searching an optimal recording strategy can also be performed by means of changing the recording strategy in various manners; however, in this case, the recording of data involves consumption of much time.

### SUMMARY OF THE INVENTION

The present invention provides an optical disk drive where data can be recorded by means of readily setting an optimal recording strategy.

The present invention provides an optical disk drive which sets a recording strategy used for defining a pulse value, a pulse width, and a pulse interval of recording pulses and which records data on an optical disk according to the recording strategy, the drive comprising: means for reading identification information about the optical disk; means for storing, in the form of a strategy table, recording strategies for respective pieces of identification information and strategies for respective recording speeds; means for setting, on the basis of the read identification information, a recording strategy for each of the pieces of identification information and for each of the recording speeds by reference to the strategy table; test data recording means for setting a reference strategy appropriate to the recording speed and recording test data in a test area of the optical disk by means of a reference strategy and an adjustment strategy, which is determined by changing a pulse width of the reference strategy, when a recording strategy based on the identification information cannot be set by the means for setting; detection means for reproducing the reference strategy and the test data, which have been recorded by means of the adjustment strategy, to thereby detect synchronizing signals of the reproduced test data; and data recording means which compares the rate of detection of the synchronizing signal with a predetermined value and which records data in a data area of the optical disk in accordance with a strategy by means of which the rate of detection becomes a predetermined value or more.

In the present invention, test data are recorded by means of the reference strategy, as well as by means of the adjustment strategy determined by changing the reference strategy. A rate of detection of a synchronizing signal included in a signal reproduced from the test data is compared with a predetermined value, to thus seek an optimal recording strategy. Since whether or not the strategy is optimal is determined by means of comparing the rate of detection of the synchronizing signal with the predetermined value, an optimal strategy can be set simply and reliably.

According to the present invention, an optimal strategy can be readily set for all optical disks, and recording quality can be enhanced.

### BRIEF DESCRIPTION OF THE DRAWINGS

Preferred embodiment of the present invention will be described in detail based on the following figures, wherein:

FIG. 1 is a block diagram of an entire optical disk drive according to an embodiment of the present invention;

FIG. 2A is a descriptive view of a synchronizing signal; i.e., a descriptive view of a synchronizing signal of a mark;

FIG. 2B is a descriptive view of a synchronizing signal; i.e., a descriptive view of a synchronizing signal of a space;

FIG. 3 is a descriptive view of a standard strategy and an adjustment strategy;

FIG. 4 is another descriptive view of the standard strategy and the adjustment strategy;

FIG. 5 is still another descriptive view of the standard strategy and the adjustment strategy;

FIG. 6 is yet another descriptive view of the standard strategy and the adjustment strategy;

FIG. 7 is a processing flowchart of the embodiment; and

FIG. 8 is a descriptive view of polarities (a mark/a space) of the synchronizing signal.

### DETAILED DESCRIPTION OF THE PREFERRED EMBODIMENT

An embodiment of the present invention will be described hereinbelow by reference to the drawings.

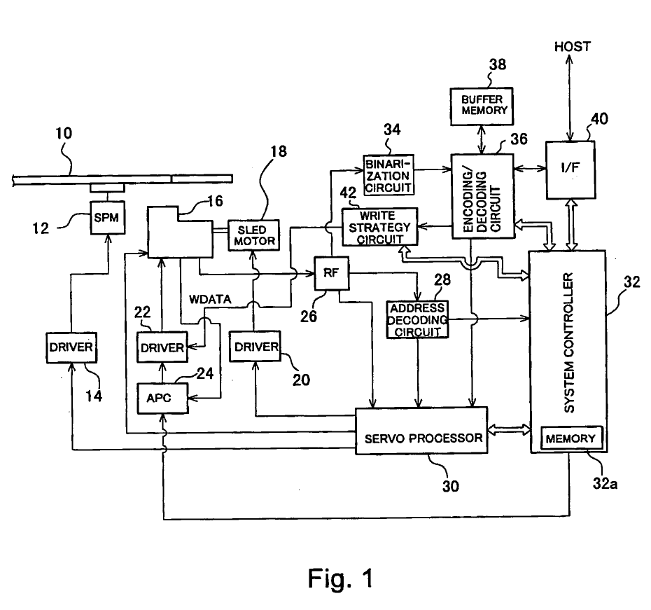

FIG. 1 shows a block diagram of an entire optical disk drive according to an embodiment of the present invention. A recordable optical disk 10, such as a DVD−R, a DVD+R, a DVD−RW, a DVD+RW, a DVD−RAM, or the like, is rotationally driven by a spindle motor (SPM) 12. The spindle motor SPM 12 is driven by a driver 14, and the driver 14 is servo-controlled by a servo processor 30 so as to attain a desired rotational speed.

An optical pickup 16 includes a laser diode (LD) which is used for radiating a laser beam onto the optical disk 10 and a photodetector (PD) which receives light reflected from the optical disk 10 and converts the thus-received light into an electrical signal. The optical pickup 16 is disposed opposite the optical disk 10. The optical pickup 16 is driven by a sled motor 18 in the radial direction of the optical disk 10, and the sled motor 18 is driven by a driver 20. The driver 20 is servo-controlled by the servo processor 30 as in the case of the driver 14. The LD of the optical pickup 16 is driven by a driver 22, and the driver 22 is controlled by an automatic power control circuit (APC) 24 such that a drive current assumes a desired value. The APC 24 controls a drive current of the driver 22 such that optimal recording power, which has been selected by means of OPC (Optimum Power Control) performed in a test area (PCA) of the optical disk 10, is acquired. OPC corresponds to processing for: recording test data in the PCA of the optical disk 10 by means of changing recording power in a plurality of steps; reproducing the test data to evaluate signal quality of the test data; and selecting recording power at which desired signal quality is acquired. A β value, a γ value, the degree of modulation, a jitter, or the like, is used as signal quality.

When the data recorded on the optical disk 10 are reproduced, the laser beam of reproducing power is emitted from the LD of the optical pickup 16, and the resultant reflected light is converted into an electric signal by the PD. The thus-converted electrical signal is output. A reproduced signal output from the optical pickup 16 is supplied to an RF circuit 26. The RF circuit 26 generates a focus error signal and a tracking error signal from the reproduced signal, and supplies the signals to the servo processor 30. On the basis of the error signals, the servo processor 30 servo-controls the optical pickup 16, thereby maintaining the optical pickup 16 in an on-focus state and an on-track state. The RF circuit 26 supplies to an address decoding circuit 28 an address signal included in the reproduced signal. The address decoding circuit 28 demodulates address data pertaining to the optical disk 10 from the address signal, and supplies the thus-demodulated address data to the servo processor 30 and a system controller 32. An example of the address signal is a wobble signal. A track of the optical disk 10 is wobbled by means of a modulated signal of time information which shows the absolute address of the optical disk 10. Address data (ATIP) can be obtained by means of extracting the wobble signal from the reproduced signal and decoding the thus-extracted wobble signal. In the case of a DVD−RW disk, address data can be acquired in accordance with a land prepit scheme. In the case of a DVD-RAM disk, address data can be acquired in accordance with a complimentary allocated pit addressing (CAPA) scheme, and address data exist in a header section recorded in a sector. The RF circuit 26 supplies a reproduced RF signal to a binarization circuit 34. The binarization circuit 34 binarizes the reproduced signal, and supplies the resultantly-produced EFM signal (for a CD disk)/8-16 modulated signal (for a DVD disk) to an encoding/decoding circuit 36. The encoding/decoding circuit 36 includes a synchronizing signal detector, and detects the synchronizing signal. Moreover, the encoding/decoding circuit 36 subjects the binarized signal to EFM demodulation/8-16 demodulation and error correction to thus produce reproduced data; and outputs the thus-reproduced data to a host apparatus, such as a personal computer, by way of an interface I/F 40. When the reproduced data are output to the host apparatus, the encoding/decoding circuit 36 outputs the reproduced data after having temporarily stored the same in buffer memory 38.

When data are recorded on the optical disk 10, data to be recorded, which have been input by way of the host apparatus, are supplied to the encoding/decoding circuit 36 by way of the interface I/F 40. The encoding/decoding circuit 36 stores in the buffer memory 38 the data to be recorded; encodes the data to be recorded; and supplies the thus-encoded data to a write strategy circuit 42 as EFM data or 8-16 modulated data. The write strategy circuit 42 converts the EFM data into multiple pulses (a pulse train) in accordance with a recording strategy set by the system controller 32, and supplies the thus-converted multiple pulses to the driver 22 as recording data. As mentioned above, a recording strategy is defined by a pulse value, a pulse width, and a pulse interval. In the case of the multiple pulses, the recording strategy is formed from a pulse width of a leading pulse or a pulse width of a subsequent pulse in the multiple pulses, or a pulse interval (a pulse duty). In the present embodiment, the recording strategy is set along with OPC. The laser beam whose power has been modulated by the recording data is emitted from the LD of the optical pickup 16, whereupon data are recorded on the optical disk 10. Data recording is performed on a per-packet basis. After the data have been recorded on a per-packet basis, the optical pickup 16 emits a laser beam of reproduction power to thereby reproduce the recorded data, and supplies the thus-reproduced data to the RF circuit 26. The RF circuit 26 supplies the reproduced signal to the binarization circuit 34, and supplies the binarized EFM data or 8-16 modulated data to the encoding/decoding circuit 36. The encoding/decoding circuit 36 decodes the EFM data or 8-16 modulated data, and verifies the thus-decoded data against the recorded data stored in the buffer memory 38. A result of verification is supplied to the system controller 32. In accordance with the result of verification, the system controller 32 determines whether to successively record data or to carry out alternation processing.

There will now be described a method for setting a recording strategy in the system controller 32 by means of such a configuration.

The system controller 32 has memory 32a, and this memory 32a stores a recording strategy for each optical disk 10 and each recording speed. As mentioned above, various manufacturers deliver the optical disks 10, and recording characteristics of the optical disks are also various. For these reasons, an optimal recording strategy has been stored in advance in the memory 32a in accordance with the type of the optical disk 10. Identification information about the optical disk 10 is read from the lead-in area, and a corresponding optimal recording strategy is read from a table. The thus-read identification information and the recording strategy are set, thereby enabling assurance of recording quality. Even in the case of the same optical disk 10, the optimal recording strategy is changed as a result of a change having arisen in recording speed. Therefore, the table stores an optimal recording strategy for each combination of optical disk 10 and recording speed.

In consideration of a case where identification information cannot be read from the lead-in area of the optical disk 10 or where corresponding identification information is not present in a table even when having been read, a standard recording strategy can be stored in the table on a per-recording-speed basis. The standard recording strategy is an average recording strategy for the optical disks 10 of all types acquired at, e.g., a certain recording speed. Example specifics of the table are schematically shown below.

TABLE 1

MANUFACTURER

| SPEED | A1 | A2 | A3 | A4 | STANDARD |
|---|---|---|---|---|---|
| N1 | S11 | S12 | S13 | S14 | S1r |
| N2 | S21 | S22 | S23 | S24 | S2r |
| N3 | S31 | S32 | S33 | S34 | S3r |

The term “manufacturer” designates identification information about the optical disk 10. A manufacturer ID, which consists of a 12-byte ASCII code, is stored in the lead-in area of the optical disk 10. This manufacture ID corresponds to identification information. The term “standard” signifies nonpresence of identification information. S11 designates a recording strategy optimal for the case of a recording speed N1 and identification information A1. In the case of, e.g., multiple pulses, the optimal recording strategy is formed from the pulse width of a leading pulse, the pulse width of a subsequent pulse, and a pulse interval. S1r designates an average recording strategy at the recording speed N1, which is an average of recording strategies of S11, S12, S13, and S14. For instance, the width of a leading pulse for S1r is an average of widths of the leading pulses for S11 to S14.

Recording strategies for all the optical disks 10 can be set as mentioned above. However, there is no guarantee that S1r, S2r, and S3r are optimal recording strategies, nor is recording quality ensured.

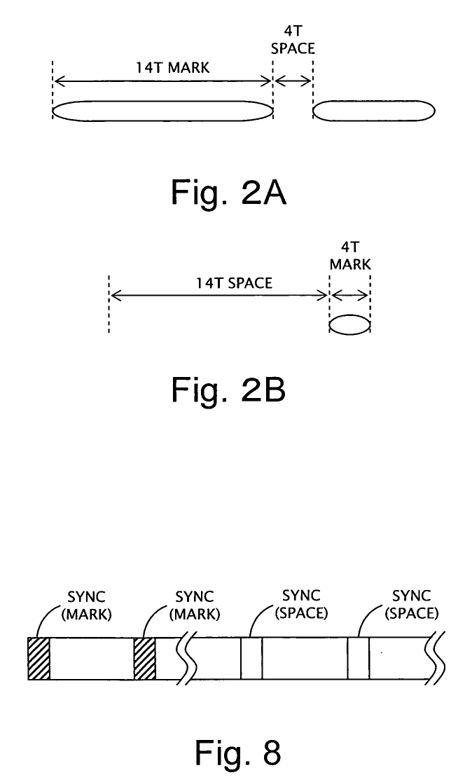

Accordingly, the system controller 32 takes a standard recording strategy as a reference strategy. Test data are recorded by means of this reference strategy, and the test data are also recorded by means of an adjustment strategy that is determined by means of changing the reference strategy by a predetermined amount. A synchronizing signal, which is generated at the time of reproduction of the test data, is detected. In the case of the DVD, the synchronizing signal is set to a maximum length of 14 T (T represents a reference length). In the case of an HD DVD, the synchronizing signal is set to 13 T, and a pseudo minimum pattern appears while being linked to the synchronizing signal. FIGS. 2A and 2B show a synchronizing signal pattern of the DVD. The synchronizing signal is formed from either marks (i.e., formation of pits) or spaces (formation of areas other than pits). Hence, two types of synchronizing signals exist. FIG. 2A shows a case where the synchronizing signal of 14 T is formed from marks, and 14 T (a mark) is followed by a space of 4 T. FIG. 2B shows a case where the synchronizing signal of 14 T is formed from a space. 14 T (a space) is followed by 4 T (a mark). In either case, data of the maximum length and data of the minimum length are consecutively present in the manner of 14 T→4 T. Since the synchronizing signal assumes extreme values in connection with the length of data, the synchronizing signal sensitively reacts with recording conditions, and deterioration of the recording conditions is reflected directly on the synchronizing signal. For this reason, in the present embodiment, attention is paid to this fact. Attention is paid to a synchronizing signal of test data, and a determination is made as to whether or not a recording strategy, which corresponds to recording conditions, is appropriate, by means of a rate of detection (hereinafter called a “detectability factor”) of the synchronizing signal.

Specifically, test data are recorded by means of a reference strategy, and the detectability factor of the synchronizing signal is computed. Further, the test data are also recorded by means of an adjustment strategy which is determined by changing the reference strategy, and the detectability factor of a resultantly-obtained synchronizing signal is computed. The strategy whose detectability factor assumes a predetermined value or more is set as a recording strategy optimal for the optical disk 10, and is delivered as a command to the write strategy circuit 42. The synchronizing signal is present in the number of 26 in one sector, and one ECC block is formed from 16 sectors. Accordingly, detectability factor can be computed by the equation of detectability factor=the number of detected synchronizing signals/(26×16). Since the synchronizing signal is formed from a mark or a space, the detectability factor of the synchronizing signal formed from the mark and the detectability factor of the synchronizing signal formed from the space are respectively computed. The thus-detected detectability factors are preferably compared with a predetermined value. A denominator of the detectability factor assumes 26×16×m (“m” designates the appearance frequency of a polarity of each of the synchronizing signals). The predetermined value is set to, e.g., 90%. The adjustment strategy may be single or plural. Use of a plurality of adjustment strategies, which are changed in different directions with reference to the reference strategy, is preferable.

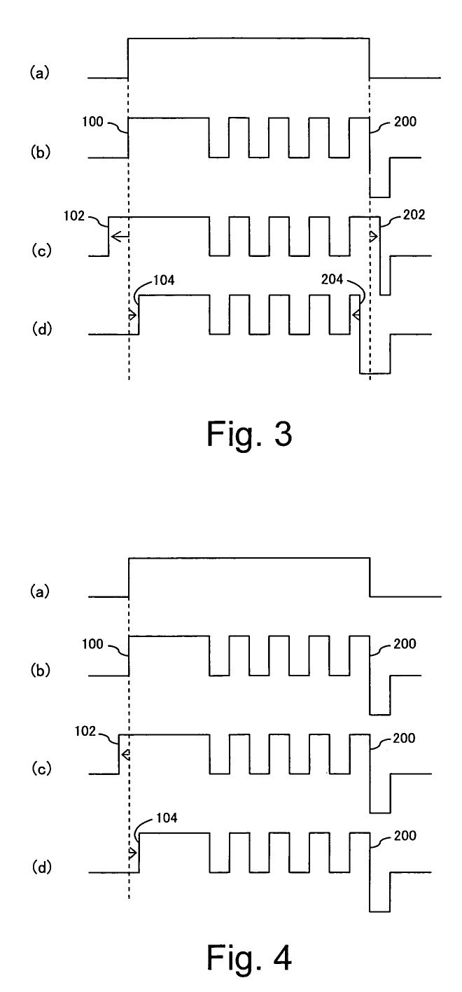

FIG. 3 shows example reference strategies in relation to a certain recording data length and example adjustment strategies in relation to the same. Reference symbol (a) designates the waveform of a certain recording data length, and reference symbol (b) designates a reference strategy used for recording data of that recording data length. The reference strategy corresponds to multiple pulses and includes a leading pulse and subsequent pulses. The multiple pulses have a pulse value which is determined by super imposing an erasing power value and a recording power value on a reproducing power value. Such reference strategies include the adjustment strategy generated by means of changing rise timing 100 of the leading pulse and falling timing 200 of the final pulse among subsequent pulses, with reference to the direction of the time axis. Reference symbol (c) designates an adjustment strategy, where rise timing 102 is set by means of advancing the rise timing 100 with reference to the reference strategy designated by reference (b), and fall timing 202 is determined by means of delaying the fall timing 200. Reference symbol (d) designates another adjustment strategy, where rise timing 104 is determined by delaying the rise timing 100 with reference to the reference strategy designated by reference symbol (b), and fall timing 204 is determined by means of advancing the fall timing 200. The rise timings 100, 102, and 104 are assumed to affect the lengths 14 T and 4 T, and the fall timings 200, 202, and 204 are assumed to particularly affect the length 14 T. Consequently, conditions for recording a synchronizing signal are changed by means of adjusting these timings, so that the detectability factor of the synchronizing signal can be changed. The amounts of changes in the rise timing 100 and the fall timing 200 may be predetermined values and changed in a plurality of steps.

FIG. 4 shows another adjustment strategy with reference to the reference strategy. Reference symbols (a), (b) are equal to reference symbols (a), (b) shown in FIG. 3, respectively. Reference symbol (c) designates an adjustment strategy, where the rise timing 102 is determined by advancing only the rise timing 100 of the reference strategy. Reference symbol (d) designates another adjustment strategy, where the rise timing 104 is determined by delaying only the rise timing 100 of the reference strategy.

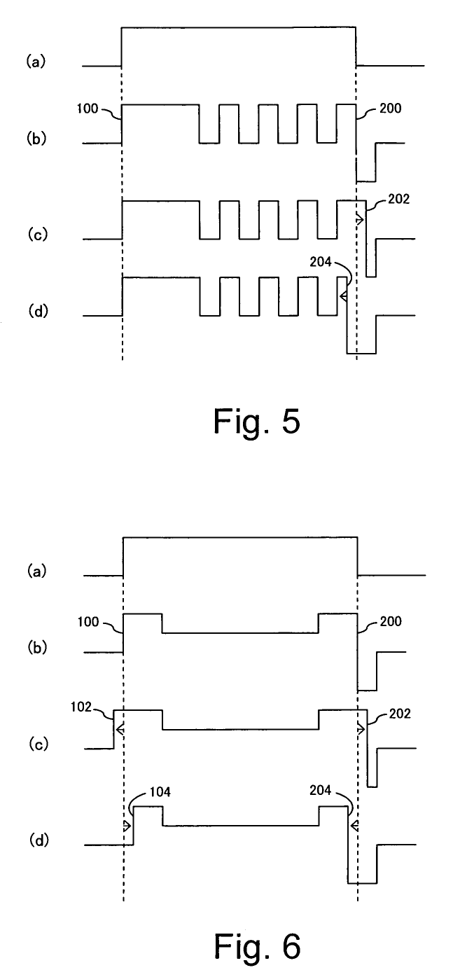

FIG. 5 shows still another adjustment strategy with reference to the reference strategy. Reference symbols (a), (b) are equal to reference symbols (a), (b) shown in FIG. 3, respectively. Reference symbol (c) designates an adjustment strategy, where the fall timing 202 is determined by delaying only the fall timing 200 of the reference strategy. Reference symbol (d) designates an adjustment strategy, where the fall timing 204 is determined by advancing only the fall timing 200 of the reference strategy.

FIG. 6 shows yet another adjustment strategy with reference to the reference strategy. This strategy is to be used for a recording speed which is faster than the recording speeds for which the reference strategies shown in FIGS. 3 to 5 are used. Reference symbol (b) designates a reference strategy, which assumes the form of a single pulse rather than multiple pulses. The pulse value includes a reproduction power value, a recording power value, a peak value, and an erasing power value. Reference symbol (c) designates an adjustment strategy, where the rise timing 102 is determined by advancing the rise timing 100 of the reference strategy and the fall timing 202 is determined by delaying the fall timing 200.

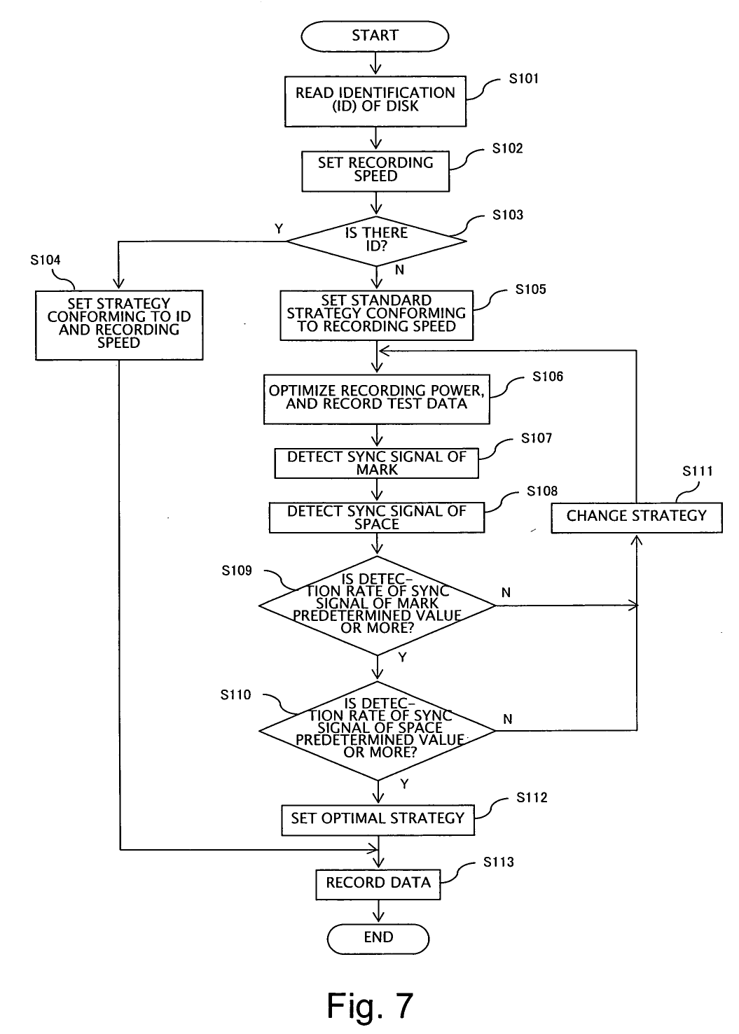

FIG. 7 shows a processing flowchart of the present embodiment. First, the optical pickup 16 is caused to seek the optical disk 10 up to a lead-in area thereof, and a laser beam of reproducing power is radiated onto the lead-in area, to thus read identification information (S101). The thus-read identification information is supplied from the encoding/decoding circuit 36 to the system controller 32. Next, the recording speed is set by the user or automatically set by the system (S102). The system controller 32 determines whether or not the identification information (ID) is present (S103). When the identification information has been read and coincides with any one of the pieces of the identification information stored in a table of the memory 32a, the identification information is determined to be valid, and a recording strategy appropriate to the identification information and the recording speed is set by reference to the table (S104). In contrast, when the reading of identification information has failed, or when corresponding identification information is not in the table even when the identification information is present, the identification information is determined to be invalid in S103, and the system controller 32 performs processing provided below.

First, reference is made to the table, to thus set a standard strategy appropriate to the recording speed (S105). The standard strategy corresponds to S1r, S2r, or the like in Table 1, and to reference symbol (b) in FIG. 3, reference symbol (b) in FIG. 6, or the like, as well. Since optimal recording power can also be changed in accordance with the recording strategy, optimal recording power in the standard strategy is searched by means of carrying out OPC (S106). After the recording power has been optimized, test data are recorded in the test area of the optical disk 10 by means of the recording power, and the test data are reproduced to thus detect a synchronizing signal of a mark (S107) and a synchronizing signal of a space (S108). In order to detect the synchronizing signal of the mark and the synchronizing signal of the space, the polarity of the synchronizing signal must be set so as to include both a mark and a space during recording of the test data. When data are recorded in the data area of the optical disk 10, the polarity of the synchronizing signal must also be controlled such that DSV is minimized. In contrast, when test data are recorded in the test area, DSV does not need to be minimized, and hence the polarity of the synchronizing signal can be set freely. The polarity of the system controller 32 is set such that the appearance frequency of the synchronizing signal of the mark becomes substantially equal to the appearance frequency of the synchronizing signal of the space. FIG. 8 schematically shows the pattern of a synchronizing signal where the appearance frequency of a mark and that of a space each become one-half. In the drawing, hatched areas designate a synchronizing signal SYNC of the mark. In this pattern, a polarity is switched to the opposite polarity after the polarity of the mark and that of the space have consecutively appeared twice, in the manner of a mark, a mark, a space, a space, . . . . Polarities may be switched alternatively as a mark, a space, a mark, and a space.

After the synchronizing signal of the mark and that of the space have been detected, the detectability factor of the synchronizing signal of the mark and the detectability factor of the synchronizing signal of the space are computed, thereby determining whether or not the detectability factor of the mark is a predetermined value or more (S109). When the detectability factor of the synchronizing signal of the mark is a predetermined value or more, a determination is made as to whether or not the detectability factor of the synchronizing signal of the space is a predetermined value or more (S110). When the detectability factor of the synchronizing signal of the mark and the detectability factor of the synchronizing signal of the space are the predetermined values or more, a strategy achieved at this time (i.e., the reference strategy in this case) is determined not to cause any problem when data are recorded according to this strategy. The strategy is set to an optimal strategy (S112). In contrast, when one or both of the detectability factor of the synchronizing signal of the mark and the detectability factor of the synchronizing signal of the space are smaller than a predetermined value, a strategy achieved at this time is determined not to be appropriate. The strategy is changed to an adjustment strategy (S111). Example adjustment strategies are illustrated in FIGS. 3 to 6. After the strategy has been changed to an adjustment strategy, processing subsequent to S106 is again repeated. Specifically, optimal recording power in the adjustment strategy is set, and test data are recorded at the optimal recording power. The detectability factor of the synchronizing signal of a mark and the detectability factor of the synchronizing signal of a space are computed, and the thus-computed detectability factors are compared with predetermined values. In one case, even when the test data have been recorded by means of the adjustment strategy and the synchronizing signal has been detected, the detectability factor of the synchronizing signal of the mark is still smaller than the predetermined value. In such a case, the strategy is again changed. Through above-described operations, an optimal strategy is set, and data are recorded in the data area of the optical disk 10 by means of the optimal strategy (S113).

An explanation is given by reference to FIG. 3. Test data are recorded by means of the reference strategy designated by reference symbol (b) in FIG. 3, and the detectability factor of the synchronizing signal is compared with a predetermined value. When one of the detectability factor of the synchronizing signal of the mark and the detectability factor of the synchronizing signal of the space is smaller than a respective predetermined value, the strategy is changed to an adjustment strategy indicated by reference symbol (c) in FIG. 3, and similar processing is repeated. When one of the detectability factor of the synchronizing signal of the mark and the detectability factor of the synchronizing signal of the space is still smaller than the respective predetermined value even after the strategy has been changed to the adjustment strategy designated by (c) in FIG. 3, the strategy is changed to the adjustment strategy designated by (d) in FIG. 3, and similar processing is repeated. When both the detectability factor of the synchronizing signal of the mark and the detectability factor of the synchronizing signal of the space have become the predetermined values or more by means of the adjustment strategy designated by (d) in FIG. 3, the adjustment strategy designated by (d) in FIG. 3 is set as an optimal strategy, and data are recorded.

When neither the reference strategy nor the adjustment strategy makes the detectability factor of the synchronizing signal of the mark and the detectability factor of the synchronizing signal of the space equal to the respective predetermined value or more, the rise or fall timing of the adjustment strategy or the amount of changes in both the risen and fall timings may be increased. In the case of the reference strategy, both the detectability factor of the synchronizing signal of the mark and the detectability factor of the synchronizing signal of the space are smaller than the predetermined values. However, in the case of a certain adjustment strategy, when the detectability factor of the synchronizing signal of the mark becomes greater than the predetermined value, the adjustment strategy may be set as an optimal strategy. In the embodiment shown in FIG. 3, both the detectability factor of the synchronizing signal of the mark and the detectability factor of the synchronizing signal of the space are smaller than the predetermined values in the case of the strategies designated by reference symbols (b) and (c). However, in the case of the strategy designated by reference symbol (d), when the detectability factor of the synchronizing signal of the mark becomes the predetermined value or more, the strategy designated by reference symbol (d) is set to an optimal strategy.

In the present embodiment, attention is paid to the synchronizing signal of the test data, and a determination is made as to whether or not the recording strategy is optimal, by means of the detectability factor of the synchronizing signal. Hence, an optimal recording strategy can be set readily. Moreover, the synchronizing signal detector is a circuit which is indispensable for demodulating the data recorded on the optical disk 10. This synchronizing signal detector can be used, in unmodified form, for setting an optimal recording strategy. Accordingly, neither a problem of an increase in the number of components nor a problem of complication of a circuit arises.

In the present embodiment, the detectability factor of the synchronizing signal of the mark and the detectability factor of the synchronizing signal of the space are computed, and the computing results are compared with predetermined values. However, as more simplified processing, only the detectability factor of a synchronizing signal of a mark or the detectability factor of a synchronizing signal of a space may be computed, and the result of computation maybe compared with a predetermined value. Specifically, the polarity of a synchronizing signal in test data is set solely for a mark, and the synchronizing signal of the mark is detected by means of reproducing the test data. The detectability factor of the synchronizing signal is computed. Alternatively, the polarity of a synchronizing signal in test data is set solely for a space, and the synchronizing signal of the space is detected by reproducing the test data. The detectability factor of the synchronizing signal is computed.

What is claimed is:

1. An optical disk drive for recording data on an optical disk, comprising:
means for reading identification information about the optical disk;
means for storing, in the form of a strategy table, recording strategies for respective pieces of identification information and strategies for respective recording speeds;
means for setting, on the basis of the read identification information, a recording strategy for each of the pieces of identification information and for each of the recording speeds by reference to the strategy table;
test data recording means for setting a reference strategy appropriate to the recording speed and recording test data in a test area of the optical disk by means of a reference strategy and an adjustment strategy, which is determined by changing a pulse width of the reference strategy, when a recording strategy based on the identification information cannot be set by the means for setting;
detection means for reproducing the test data which have been recorded by means of the reference strategy and the adjustment strategy, to thereby detect synchronizing signals of the reproduced test data; and
data recording means for selecting a strategy, from the reference strategy and the adjustment strategy, at which a rate of detection of the synchronizing signal becomes a predetermined value or more, and for recording data in the data area of the optical disk.

2. The optical disk drive according to claim 1, wherein the test data recording means records, as the test data, test data where a mark and a space in the synchronizing signal appear at essentially the same frequency;
the data recording means selects, among the reference strategy and the adjustment strategy, a strategy by means of which a rate of detection of a synchronizing signal of the mark and a rate of detection of a synchronizing signal of the space become predetermined values or more, and records data.

3. The optical disk drive according to claim 1, wherein the adjustment strategy is a strategy which is determined by changing at least rise timing of a leading pulse in the reference strategy or a fall timing of a final pulse in the reference strategy.

4. The optical disk drive according to claim 2, wherein, when any of the rate of detection of the synchronizing signal of the mark and the rate of detection of the synchronizing signal of the space is smaller than the respective predetermined value, the test data recording means is taken as a new adjustment strategy by means of further changing the pulse width of the adjustment strategy.

5. The optical disk drive according to claim 2, wherein the data recording means selects a strategy, from the reference strategy and the adjustment strategy, by means of which the rate of detection of the synchronizing signal of only the mark becomes the predetermined value or more although both the rate of detection of the synchronizing signal of the mark and the rate of detection of the synchronizing signal of the space are not the predetermined value or more; and records data.

6. The optical disk drive according to claim 2, wherein the test data recording means records, as the test data, test data including a mark as a synchronizing signal; and
the data recording means selects, from the reference strategy and the adjustment strategy, a strategy by means of which the rate of detection of the synchronizing signal of the mark becomes a predetermined value or more, and records data.

7. The optical disk drive according to claim 2, wherein the test data recording means records, as the test data, test data including a space as a synchronizing signal; and
the data recording means selects, from the reference strategy and the adjustment strategy, a strategy by means of which the rate of detection of the synchronizing signal of the space becomes a predetermined value or more, and records data.

8. The optical disk drive according to claim 1, wherein the reference strategy is an average recording strategy of recording strategies achieved at a plurality of recording speeds.

9. An optical disk drive for recording data on an optical disk, comprising:
means for recording test data in a test area of the optical disk by means of a standard strategy appropriate to a recording speed and an adjustment strategy which is determined by changing a pulse width of the standard strategy;
means for reproducing the test data and detecting a synchronizing signal; and
means for selecting one from the standard strategy and the adjustment strategy by means of comparing performance of the standard strategy for detecting the synchronizing signal with performance of the adjustment strategy for detecting the synchronizing signal, and for recording data in a data area of the optical disk by means of the selected strategy.

10. The optical disk drive according to claim 9, wherein the standard strategy is an average recording strategy of recording strategies achieved at a plurality of recording speeds; and
the adjustment strategy is at least one of a first adjustment strategy determined by changing rise timing of the standard strategy, a second adjustment strategy determined by changing fall timing of the standard strategy, and a third adjustment strategy determined by changing both rise and fall timings of the standard strategy.
